(19) United States
(12) Patent Application Publication
(10) Pub. No.: US 2012/0139559 A1
(43) Pub. Date: Jun. 7, 2012

(54) POSITIONING SYSTEM FOR A TRAVELING TRANSFER SYSTEM

(75) Inventor: Heinrich van de Loecht, Muggensturm (DE)

(73) Assignee: ROBERT BOSCH GMBH, Stuttgart (DE)

(21) Appl. No.: 13/265,570

(22) PCT Filed: Apr. 1, 2010
(86) PCT No.: PCT/EP2010/054427

§ 371 Date: Oct. 21, 2011

(30) Foreign Application Priority Data
May 13, 2009 (DE) 102009003080.8

(51) Int. Cl. G01R 27/28

(52) U.S. Cl. 324/654

(57) ABSTRACT

The invention relates to a positioning system (1) for a traveling transfer system, comprising a traveling transport belt (2), at least one traveler (3) which travels on the transport belt (2), and a positioning device (4) having a plurality of position sensors (5) which are arranged on the transport belt (2), the position sensors (5) being arranged in a first row (6) and a second row (7), the first row (6) being parallel to the second row (7), and the position sensors (5) being arranged in the direction of travel (A) in the first and second row (6, 7) in such a manner that the free ends of the position sensors (5) form overlapping sections (16) at a right angle to the direction of travel (A).

### BACKGROUND OF THE INVENTION

The present invention relates to a positioning system for a traveling transfer system which is used, in particular, in packaging machine technology.

Traveling transfer systems are used, for example, in the field of packaging machines in order to load the latter with goods to be packaged, for example bars of chocolate, bags, bottles, etc. In this case, such traveling transfer systems have a traveling transport section as well as a multiplicity of travelers which travel around the transport section and carry out the transport tasks in the process. When more than one traveler is used in particular, it would be advantageous to determine the exact position of the travelers in order to control the latter. This is advantageous, in particular, when the travelers can be driven independently of one another at different speeds and relative positions between the individual travelers can therefore change.

DE 43 35 004 C2 discloses a measuring system having a sensor, in which a defined electrical resistance section and a contact electrode which follows the course of the path of the resistance section are arranged at an insulating distance, a position of the contact being able to be determined when making contact between the contact electrode and the resistance section. However, such a sensor is not undoubtedly suitable for a traveling transfer system since it does not operate without wear and, in particular, has high production costs.

### SUMMARY OF THE INVENTION

In contrast, the positioning system according to the invention has the advantage that it operates without wear and provides a very cost-effective absolute displacement measuring system. A modular design is also possible in this case, with the result that any desired transport sections can be equipped with the positioning system according to the invention. Another great advantage of the positioning system according to the invention can be seen in the fact that there is no need for an active sensor on the travelers, with the result that it is possible to avoid supplying electrical energy and transmitting measurement signals to and from the traveler. This is achieved, according to the invention, by virtue of the fact that the positioning system has a positioning device having a multiplicity of position sensors which are arranged on the transport section. In this case, the position sensors are provided in two rows which are arranged parallel to one another. In this case, the position sensors have free ends which form overlapping regions perpendicular to the direction of travel. This makes it possible to reliably determine a position of any traveler arranged on the transport section according to the invention.

A length of each position sensor in the direction of travel is particularly preferably the same as or greater than a length of a detector region of the traveler in the direction of travel. This ensures that individual position sensors can only be covered by one respective traveler at the same time.

The detector region of the traveler is also preferably arranged laterally beside the position sensors in the two rows which are parallel to one another, with the result that the position sensors and travelers overlap.

The two parallel rows of position sensors are also preferably arranged beside one another. Alternatively, the two parallel rows of position sensors are arranged above one another, a partition which shields magnetic fields then preferably being arranged between the two rows arranged above one another. This partition is preferably a thin sheet, in particular with a thickness in the μ range, and particularly preferably a metal foil.

In order to be able to be produced in a particularly cost-effective manner, the individual position sensors are preferably in the form of resistive or inductive sensors. Both types of sensor can be produced in a particularly cost-effective manner using screen printing in thick-film technology. In this case, conductor tracks for connecting a supply voltage and measurement signal lines are also preferably arranged on an underside of the sensors.

The design of the positioning system according to the invention can be simplified further if at least one permanent magnet is arranged on each traveler. As a result, each traveler has a defined magnetic field as a detector region, which can be used to detect the position of the traveler. Alternatively, a coil is provided for the inductive displacement measurement.

The positioning device particularly preferably comprises a sensor printed circuit board on which a plurality of position sensors are arranged. In this case, the sensor printed circuit board is arranged on the traveling transport section. This makes it possible to provide a common line for electrical supply and for measurement signal transmission for a plurality of position sensors on a sensor printed circuit board. Such lines are particularly preferably arranged on the underside of the sensor printed circuit board. A plurality of position sensors can therefore be arranged on a common sensor printed circuit board, which simplifies mounting on the traveling transfer system, in particular. The positioning system particularly preferably comprises a multiplicity of sensor printed circuit boards each having defined supporting points. As a result, any desired traveling transport sections can be equipped using individual, prefabricated sensor printed circuit board structural units, thus enabling rapid and simple adaptation to a wide variety of transport sections with standardized sensor printed circuit boards. As a result of the standardized interfaces, differently shaped sensor printed circuit boards can be combined with one another as desired in this case. Straight sections, 90° curves, 180° curves or curves with any other desired arc lengths, for example 45° or 120°, can be provided as individual sensor printed circuit board components, for example. In this case, the individual sensor printed circuit boards preferably have a common electrical supply and/or common measuring lines which is/are preferably arranged on the underside of the sensor printed circuit boards, whereas the position sensors are arranged on a top side of the sensor printed circuit boards.

### BRIEF DESCRIPTION OF THE DRAWINGS

A preferred exemplary embodiment of the invention is described in detail below with reference to the accompanying drawing, in which:

FIG. 1 shows a diagrammatic side view of a positioning system according to an exemplary embodiment of the invention, and

FIGS. 2-4 show illustrations of different sensor printed circuit boards.

### DETAILED DESCRIPTION

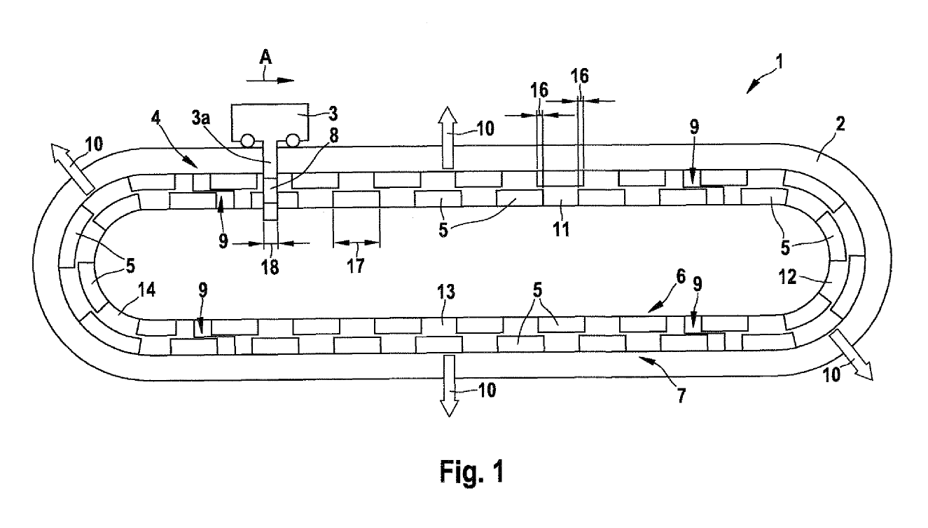

A positioning system 1 according to a preferred exemplary embodiment of the invention is described in detail below with reference to FIGS. 1 to 4.

As is clear from FIG. 1, the positioning system 1 comprises a traveling transport section 2 on which a traveler 3 is arranged in such a manner that it can travel around the transport section 2. For reasons of simplification, FIG. 1 illustrates only one traveler 3, but any desired number of travelers can be arranged on the transport section 2. In this case, the arrow A indicates a direction of travel of the traveler 3. In this case, the traveler 3 is used to convey goods, for example in order to load a packaging system.

A positioning device 4 in the form of a sensor printed circuit board is also arranged on the transport section 2. The positioning device 4 simulates the same route as the transport section 2 and is used to exactly position the traveler 3. The positioning device 4 comprises a multiplicity of position sensors 5 which are arranged in a first row 6 and in a second row 7 in this exemplary embodiment. In each row, the position sensors 5 are arranged at a distance from one another in this case, the position sensors in the second row 7 being respectively arranged at the corresponding gaps in the first row 6. In this case, the position sensors 5 are arranged in such a manner that they respectively have a short overlapping region 16 at their start in the direction of travel A and at their end in the direction of travel A. In this case, the position sensors 5 have a length 17 which is longer than a position-relevant length 18 of a detector region 3a of the traveler 3 in the direction of travel of the traveler. As is clear from FIG. 1, the position-relevant length 18 of the traveler 3 is formed by the protruding detector region 3a in this exemplary embodiment. In this case, the protruding detector region 3a is arranged laterally on the sensor printed circuit board and has a permanent magnet 8. In this case, the permanent magnet 8 is arranged in such a manner that it at least partially covers both the position sensors in the first row 6 and the position sensors in the second row 7 when the traveler 3 moves. The permanent magnet 8 thus forms a detector for the traveler 3.

In this exemplary embodiment, the position sensors 5 are each in the form of a potentiometer. In accordance with a change in a relative position of the permanent magnet 8 as a result of a movement of the traveler 3, the electrical resistance at the respective position sensor 5 changes, which connects the respective position sensor 5 as a voltage divider, as a result of which an electrical voltage which changes relative to the position of the permanent magnet 8 is obtained at the potentiometer. This makes it possible to define an exact position of the traveler 3.

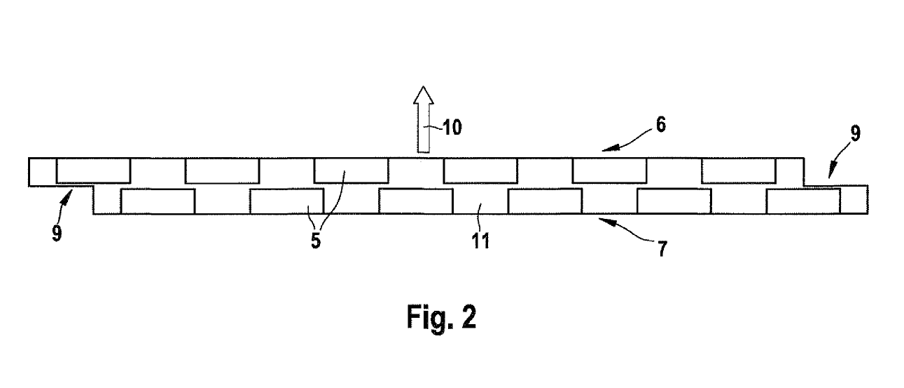

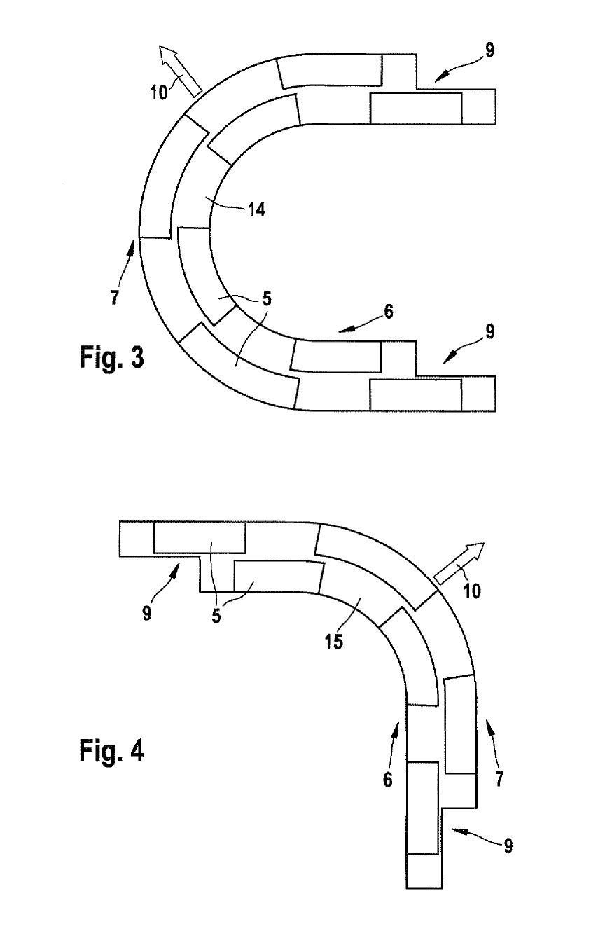

The position sensors 5 in this exemplary embodiment are in the form of potentiometers which are simple to produce, a plurality of position sensors 5 respectively being arranged on a separate printed circuit board part. In this case, the multiplicity of position sensors for each printed circuit board part have a common electrical supply and measuring line which is respectively denoted using the reference symbol 10 in the figures. As is clear from FIG. 1, the sensor printed circuit board in this exemplary embodiment is assembled from four separate printed circuit board parts 11, 12, 13, 14, the printed circuit board parts each having a defined interface 9 at their free ends. The transport section 2 in this exemplary embodiment is thus depicted by the four printed circuit board parts 11, 12, 13, 14, the printed circuit board parts 11 and 13 being rectilinear printed circuit boards parts and the printed circuit board parts 12 and 14 being 180° arcs. In this case, the defined interfaces 9 are each implemented by means of correspondingly formed recesses in the first row 6 and in the second row 7, with the result that the individual printed circuit board parts can be combined in any desired manner via the defined interfaces 9. In this case, FIGS. 2 and 3 show the printed circuit board parts used in the exemplary embodiment from FIG. 1 and FIG. 4 shows another alternative of a printed circuit board part 15 in the form of a 90° arc. It goes without saying that other printed circuit board parts which are geometrically shaped in any desired manner and have a corresponding identical interface 9 can also be provided. A modular design of the sensor printed circuit board can therefore be provided for the positioning device 4, with the result that any desired traveling transport systems can be simulated.

According to the invention, it is thus possible to always exactly determine a position of the traveler 3 since the permanent magnet 8 on the traveler 3 is operatively connected either to a position sensor 5 in the first row 6 or to a position sensor 5 in the second row 7. The overlapping areas 16 between the position sensors in the first and second rows thus ensure that there is no position on the transport section 2 at which no position sensor is arranged. The position signals obtained are supplied, via the lines 10, to a control unit (not shown) which can then pass acceleration or delay commands to the respective travelers 3 in a corresponding manner in order to maintain defined spacings or defined conveying speeds, for example. Since there is no contact between the traveler 3 and the positioning device 4, the positioning system according to the invention is completely free of wear and can be produced in a very cost-effective manner in this case. The modular design enables any desired transport sections in this case without requiring special production for the individual printed circuit board parts of the sensor printed circuit board here. Furthermore, existing transport systems can easily be extended if necessary. In addition, there are no active sensors on the traveler 3, with the result that it is possible to dispense with complicated supply of electrical energy and transmission of measurement signals from or to the traveler 3. In this case, the design of the positioning system according to the invention remains very simple and cost-effective.

1. A positioning system (1) for a traveling transfer system, the positioning system comprising:
a traveling transport section (2),
at least one traveler (3) which travels on the transport section (2), and
a positioning device (4) having a multiplicity of position sensors (5) which are arranged on the transport section (2),
the position sensors (5) being arranged in a first row (6) and in a second row (7), the first row (6) being arranged parallel to the second row (7), and
the position sensors (5) being arranged in the first and second rows (6, 7) in the direction of travel (A) in such a manner that they each have overlapping regions (16) at the free ends of the position sensors (5) perpendicular to the direction of travel (A).

2. The positioning system as claimed in claim 1, characterized in that the position sensors (5) have a length which is one of the same as or greater than a length (18) of a detector region (3a) of the at least one traveler (3) in the direction of travel (A), which detector region (3a) is operatively connected to the position sensors (5).

3. The positioning system as claimed in claim 2, characterized in that the first row (6) and the second row (7) are arranged beside one another, and the detector region (3a) on the traveler (3) laterally covers the first and second rows (6, 7).

4. The positioning system as claimed in claim 2, characterized in that the first and second rows (6, 7) are arranged above one another, and the detector region (3a) of the traveler (3) is arranged above the two rows (6, 7).

5. The positioning system as claimed in claim 4, characterized in that a partition which shields magnetic fields is arranged between the two rows (6, 7).

6. The positioning system as claimed in claim 1, characterized in that the position sensors (5) are in the form of one of resistive or inductive sensors.

7. The positioning system as claimed in claim 1, characterized in that at least one permanent magnet (8) is arranged on the traveler (3) as one of a detector for the position sensors (5) or as a coil for an inductive displacement measurement.

8. The positioning system as claimed in claim 1, characterized in that the positioning device (4) has a sensor printed circuit board on which the multiplicity of position sensors (5) are arranged, the sensor printed circuit board being arranged on an entirety of the traveling transport section (2).

9. The positioning system as claimed in claim 8, characterized in that the sensor printed circuit board comprises a multiplicity of printed circuit board parts (11-14), the printed circuit board parts (11-14) each having defined interfaces (9) at their free ends.

10. The positioning system as claimed in claim 8, characterized in that at least one of an electrical supply line and a measuring line is arranged on an underside of the sensor printed circuit board, and the position sensors (5) are arranged on a top side of the sensor printed circuit board.

11. The positioning system as claimed in claim 5, characterized in that the partition is a thin sheet.

12. The positioning system as claimed in claim 11, characterized in that the thin sheet has a thickness in a micron range.

13. The positioning system as claimed in claim 6, characterized in that the position sensors (5) are in the form of one of potentiometers or inductive displacement detectors.
